(19) United States
(12) Patent Application Publication
(10) Pub. No.: US 2026/0237333 A1
(43) Pub. Date: Aug. 13, 2026

(54) DISPLAY PANEL AND ELECTRONIC DEVICE INCLUDING THE SAME

(71) Applicant: Samsung Display Co., Ltd., Yongin-si (KR)

(72) Inventors: Jin Yup KIM, Yongin-si (KR); Tae Kyu KIM, Yongin-si (KR); Hyun Woo KIM, Yongin-si (KR); Won Young SONG, Yongin-si (KR); Young Hyun YOO, Yongin-si (KR); Byeong Guk JEON, Yongin-si (KR); Byung Su CHO, Yongin-si (KR)

(21) Appl. No.: 19/454,654

(22) Filed: Jan. 21, 2026

(30) Foreign Application Priority Data
Feb. 7, 2025 (KR) 10-2025-0015689

(51) Int. Cl. G09G 3/00; G01N 27/20

(52) U.S. Cl. CPC G09G 3/006; G01N 27/20; G09G 2330/12

(57) ABSTRACT

A display panel includes: a substrate including a display area and a non-display area; a first crack detection pad and a second crack detection pad in a pad area overlapping the non-display area; an alignment key at a corner portion of the substrate; and a crack detection wire having one end connected to the first crack detection pad and another end connected to the second crack detection pad, wherein the crack detection wire includes: a first wire portion; a second wire portion including a plurality of wires bent from the first wire portion by the alignment key; and a third wire portion connected to the second wire portion.

### CROSS-REFERENCE TO RELATED APPLICATION

The present application claims priority to and the benefit of Korean Patent Application No. 10-2025-0015689, filed on Feb. 7, 2025, in the Korean Intellectual Property Office, the entire disclosure of which is incorporated herein by reference.

### BACKGROUND

### 1. Field

Aspects of some embodiments of the present disclosure relate to a display panel and an electronic device including the display panel.

### 2. Description of the Related Art

As display devices become smaller, lighter, and thinner, it may be desirable to increase the durability of the display device against cracks, scratches, chips, and the like which may occur due to external impacts or the like.

For example, a flexible display device may be bent or crooked during manufacturing or use, and if there is even a slight crack in a substrate or stacked layers of a display panel, the slight crack may develop into a larger crack due to the bending or crooking of the display panel over time.

Therefore, it may be desirable to check whether a crack occurs in a display panel.

The above information disclosed in this Background section is only for enhancement of understanding of the background and therefore the information discussed in this Background section does not necessarily constitute prior art.

### SUMMARY

Aspects of some embodiments of the present disclosure may be directed to a system and method to prevent, reduce, or mitigate damage to a crack detection wire for checking whether a crack occurs in a display panel.

According to one or more embodiments of the present disclosure, a display panel includes: a substrate including a display area and a non-display area, a first crack detection pad and a second crack detection pad located in a pad area overlapping the non-display area, an alignment key located at a corner portion of the substrate, and a crack detection wire having one end connected to the first crack detection pad and another end connected to the second crack detection pad. According to some embodiments, the crack detection wire includes: a first wire portion, a second wire portion including a plurality of wires bent from the first wire portion by the alignment key, and a third wire portion connected to the second wire portion.

According to some embodiments, the first wire portion may include a first straight portion extending in a first diagonal direction by the alignment key, a second straight portion extending in a second diagonal direction opposite to the first diagonal direction and spaced apart from the first straight portion, a first bending portion bent at the second straight portion and extending in a third diagonal direction, and a third straight portion bent at the first bending portion, extending in the first diagonal direction, and spaced apart from the second straight portion.

According to some embodiments, the second wire portion may include a second bending portion bent at the first straight portion and extending in a fourth diagonal direction opposite to the third diagonal direction, a third bending portion bent at the second straight portion and extending in the fourth diagonal direction, and a fourth bending portion bent at the third straight portion and extending in the fourth diagonal direction.

According to some embodiments, the third wire portion may include a fourth straight portion bent at the second bending portion and extending in the first diagonal direction, a fifth bending portion bent at the fourth straight portion and extending in the third diagonal direction, a fifth straight portion bent at the fifth bending portion, extending in the second diagonal direction, and spaced apart from the fourth straight portion, and a sixth straight portion extending in the first diagonal direction and spaced apart from the fifth straight portion.

According to some embodiments, the third bending portion may be connected to the fifth straight portion.

According to some embodiments, fourth bending portion may be connected to the sixth straight portion.

According to some embodiments, a distance between the first straight portion and the second straight portion, a distance between the second straight portion and the third straight portion, a distance between the second bending portion and the third bending portion, a distance between the third bending portion and the fourth bending portion, a distance between the fourth straight portion and the fifth straight portion, and a distance between the fifth straight portion and the sixth straight portion may be the same.

According to some embodiments, the distance may be 4 μm.

According to some embodiments, a second width of each of the second bending portion, the third bending portion, and the fourth bending portion may be greater than a first width of each of the first straight portion, the second straight portion, the third straight portion, the first bending portion, the fourth straight portion, the fifth straight portion, the sixth straight portion, and the fifth bending portion.

According to some embodiments, the second width may be 4 μm and the first width may be 3 μm.

According to one or more embodiments of the present disclosure, an electronic device includes: a display panel, and a processor for driving the display panel. According to some embodiments, the display panel includes: a substrate including a display area and a non-display area, a first crack detection pad and a second crack detection pad located in a pad area overlapping the non-display area, an alignment key located at a corner portion of the substrate, and a crack detection wire having one end connected to the first crack detection pad and another end connected to the second crack detection pad. According to some embodiments, the crack detection wire includes: a first wire portion, a second wire portion including a plurality of wires bent from the first wire portion by the alignment key, and a third wire portion connected to the second wire portion.

### BRIEF DESCRIPTION OF THE DRAWINGS

The above and other aspects and characteristics of some embodiments of the present disclosure will be more clearly understood from the following detailed description of the illustrative, non-limiting embodiments with reference to the accompanying drawings.

FIG. 1 schematically illustrates a display device according to some embodiments of the present disclosure.

FIG. 2 schematically illustrates a display panel according to some embodiments of the present disclosure.

FIG. 3 is an enlarged view of area X in FIG. 2.

FIG. 4 is a diagram illustrating a measured electric field of a crack detection wire in FIG. 3.

FIG. 5 schematically illustrates a display panel according to some embodiments of the present disclosure.

FIG. 6 is an enlarged view of area Y in FIG. 5.

FIG. 7 is a diagram illustrating a measured electric field of a crack detection wire in FIG. 6.

FIG. 8 schematically illustrates a display panel according to some embodiments of the present disclosure.

FIG. 9 schematically illustrates an electronic device according to some embodiments of the present disclosure.

FIG. 10 schematically illustrates electronic devices according to some embodiments of the present disclosure.

### DETAILED DESCRIPTION

Hereinafter, aspects of some embodiments according to the present disclosure are described in more detail with reference to the accompanying drawings. It should be noted that in the following description, only portions necessary for understanding an operation according to the present disclosure may be described, and descriptions of other portions may be omitted in order not to obscure the subject matter of the present disclosure. In addition, the present disclosure may be embodied in other forms without being limited to embodiments described herein. However, embodiments of the present disclosure are described in detail in order for those skilled in the art to be able to readily implement the technical spirit of the present disclosure.

Throughout the specification, in a case where a component is “connected” to another component, the components may be “directly connected” or the components may be “indirectly connected” with another element interposed therebetween. Terms used herein are for describing specific embodiments and are not intended to limit the present disclosure. Throughout the specification, in a case where a certain portion “includes” a certain component, the portion may further include another component without excluding another component unless otherwise stated. “At least one of X, Y, and Z” and “at least one selected from a group consisting of X, Y, and Z” may be interpreted as X only, Y only, Z only, or any combination of two or more of X, Y, and Z (for example, XYZ, XY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features may be positioned in a direction “on” the other elements or features. Therefore, in the present disclosure, the term “under” may include both directions of on and under. In addition, the device may face in other directions (for example, rotated 90 degrees or in other directions) and thus the spatially relative terms used herein may be interpreted according thereto.

In addition, embodiments of the disclosure may be described here with reference to schematic diagrams (and intermediate structures) of the present disclosure, so that changes in a shape as shown due to, for example, manufacturing technology and/or a tolerance may be expected. Therefore, embodiments disclosed herein may not be construed as being limited to shown specific shapes, and should be interpreted as including, for example, changes in shapes that occur as a result of manufacturing. As described herein, the shapes shown in the drawings may not show actual shapes of areas of a device, and embodiments are not limited thereto.

Hereinafter, aspects of some embodiments of the present disclosure will be described in more detail with reference to the accompanying drawings.

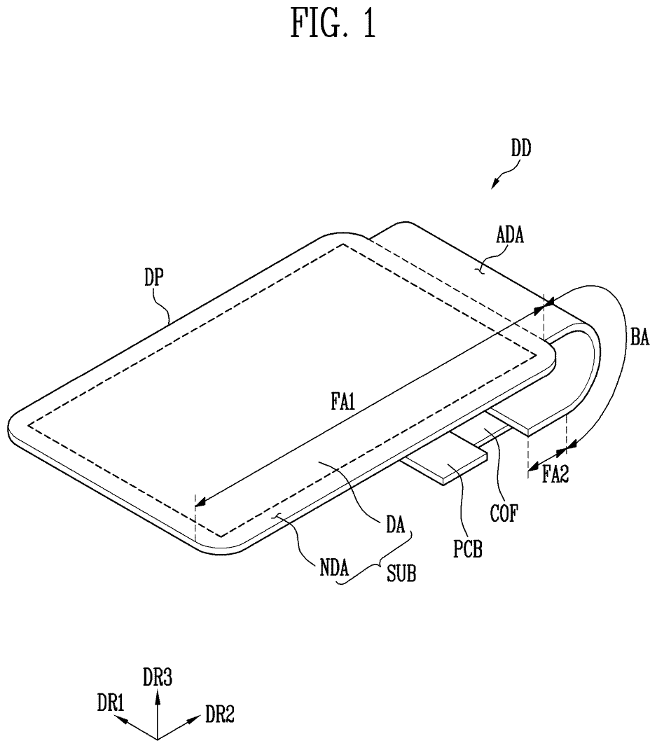

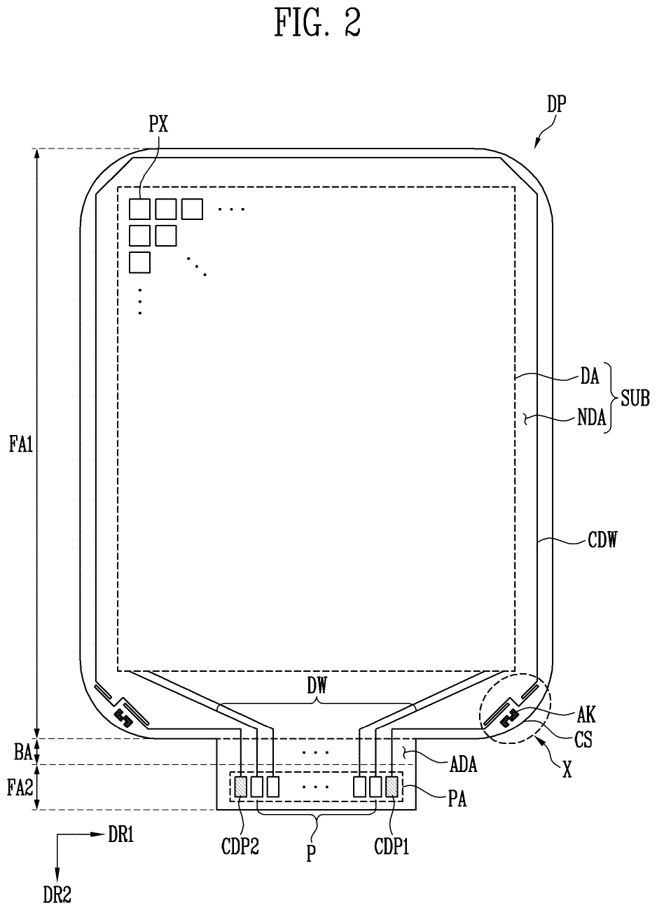

FIG. 1 schematically illustrates a display device according to some embodiments of the present disclosure. FIG. 2 schematically illustrates a display panel according to some embodiments of the present disclosure.

Referring to FIG. 1, the display device DD may include the display panel DP, a chip on film COF, and a printed circuit board PCB.

The display device DD may be applied to various electronic devices such as a foldable electronic device, a rollable electronic device, and a flat panel electronic device. In addition, the display device DD may be applied to a small electronic device such as a mobile phone, or a medium or large electronic device such as a television. However, the embodiments are not necessarily limited thereto.

Referring to FIGS. 1 and 2, the display panel DP displays images in a third direction DR3 (or the front direction), and may be bent in a bending area BA. The display panel DP may include a first flat area FA1 and a second flat area FA2 spaced apart from each other with the bending area BA interposed therebetween. The first flat area FA1 and the second flat area FA2 may be arranged parallel to each other with the bending area BA interposed therebetween.

The chip on film COF may be located between the display panel DP and the printed circuit board PCB. For example, one end of the chip on film COF may be connected to the second flat area FA2 of the display panel DP, and the other end of the chip on film COF may be connected to the printed circuit board PCB. The chip on film COF may process various signals input from the printed circuit board PCB and output the processed signals to the display panel DP.

The printed circuit board PCB may process various signals input from a processor such as an application processor or a central processing unit and output the processed signals to the chip on film COF. One end of the printed circuit board PCB may be connected to the chip on film COF, and the other end of the printed circuit board PCB may be connected to the processor. The printed circuit board PCB may include a Flexible Printed Circuit Board, but embodiments are not necessarily limited thereto.

Referring to FIG. 2, the display panel DP may include a substrate SUB, pixels PX, driving pads P, a first crack detection pad CDP1, a second crack detection pad CDP2, driving wires DW, at least one alignment key AK, and a crack detection wire CDW.

The substrate SUB may have rigid or flexible characteristics. The flexible characteristics may be interpreted in the same sense as bendable, unbreakable, rollable, foldable, or the like characteristics. The substrate SUB may include glass or plastic. For example, the substrate SUB may include one selected from the group consisting of a polyester-based polymer, a silicon-based polymer, an acrylic-based polymer, a polyolefin-based polymer, and a copolymer thereof. For example, the substrate SUB may include, but is not necessarily limited to, polyimide (PI). For example, the substrate SUB may include silicon.

The substrate SUB may have a quadrangle shape. For example, the substrate SUB may have a rectangular shape, although embodiments are not necessarily limited thereto. For example, the substrate SUB may have various shapes such as a polygon, a circle, an ellipse, or an irregular shape. Each of corner portions CS of the substrate SUB may have a rounded shape, but embodiments are not necessarily limited thereto. For example, the corner portion CS of the substrate SUB may have a rectangular shape.

The substrate SUB may include a display area DA and a non-display area NDA located on at least one side of the display area DA. According to some embodiments, the non-display area NDA may surround (e.g., in a periphery or outside a footprint of) the display area DA. The display area DA is an area which displays images, and may include the pixels PX. The display area DA may have a shape corresponding to the shape of the substrate SUB. For example, the display area DA may have a rectangular shape, and a corner portion of the display area DA has a right-angled shape, but embodiments are not necessarily limited thereto. For example, the corner portion of the display area DA may have a rounded shape. The non-display area NDA is an area which does not display images, and may include various wires such as the driving wires DW, the crack detection wire CDW, and the like, various pads such as the driving pads P, the first and second crack detection pads CDP1 and CDP2, and the like, and at least one alignment key AK.

The pixels PX may be located in the display area DA. Each of the pixels PX may generate light of various colors, such as red, green, blue, cyan, magenta, or yellow. The pixels PX may be arranged in a stripe pattern in a first direction DR1 and a second direction DR2, but embodiments are not necessarily limited thereto.

The non-display area NDA may include an additional area ADA protruding in the second direction DR2. The additional area ADA may include a pad area PA. The pad area PA may overlap the non-display area NDA. However, the embodiments are not necessarily limited thereto. For example, the pad area PA may be located in the non-display area NDA and not in the additional area ADA.

The driving pads P may be located in the pad area PA. For example, the driving pads P may be arranged in the first direction DR1 in the pad area PA. The number of driving pads P may correspond to the number of driving wires DW. For example, the driving pads P may be respectively connected to the driving wires DW. The driving pads P may provide, to the driving wires DW, driving signals transmitted through the chip on film COF and/or the printed circuit board PCB.

The first crack detection pad CDP1 may be located in the pad area PA. For example, the first crack detection pad CDP1 may be located on one side of the driving pads P. The first crack detection pad CDP1 may provide, to the crack detection wire CDW, a crack detection signal transmitted through the chip on film COF and/or the printed circuit board PCB.

The second crack detection pad CDP2 may be located in the pad area PA. For example, the second crack detection pad CDP2 may be located on the other side of the driving pads P. The second crack detection pad CDP2 may detect whether a crack occurs in the display panel DP based on the resistance of the crack detection wire CDW. For example, when a crack occurs in the display panel DP and a defect (for example, disconnection) occurs in the crack detection wire CDW, the resistance of the crack detection wire CDW may increase. The second crack detection pad CDP2 may detect whether a crack occurs in the display panel DP by measuring the changed resistance of the crack detection wire CDW.

The driving wires DW may be located in the non-display area NDA. One end of each of the driving wires DW may be connected to the corresponding driving pad P, and the other end of each of the driving wires DW may be connected to the corresponding pixels PX. The driving wires DW may provide, to the pixels PX, the driving signals transmitted through the driving pads P.

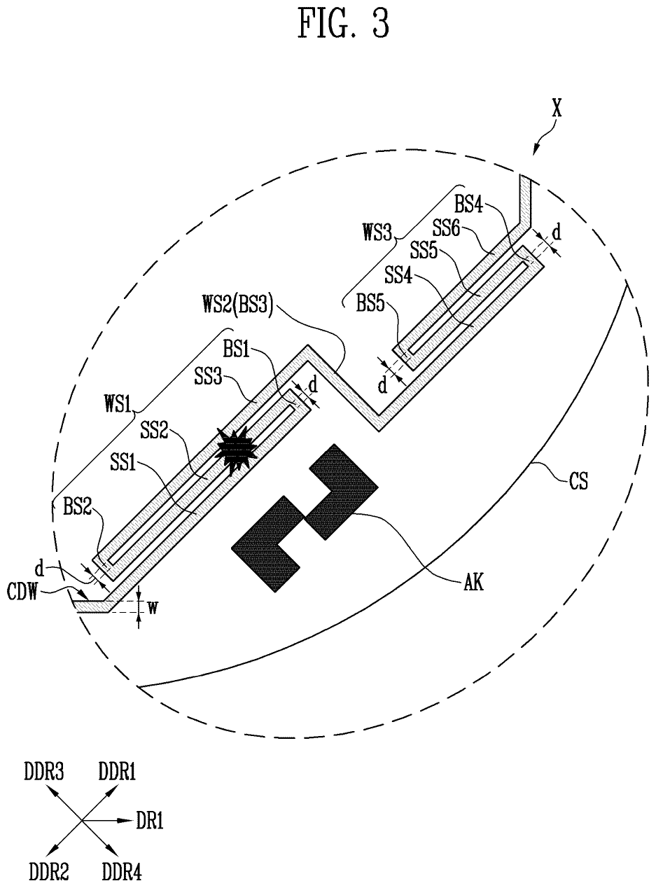

The at least one alignment key AK may be located in the non-display area NDA. For example, the alignment key AK may be located near the corner portion CS of the substrate SUB (or the display panel DP). The alignment key AK may be used to check the alignment status, or the like required during a manufacturing process. The alignment key AK may be located at each of the lower left corner portion CS and the lower right corner portion CS of the substrate SUB, but embodiments are not necessarily limited thereto. The shape of the alignment key AK is not limited to the shapes shown in FIGS. 2 and 3, and the alignment key AK may have various shapes.

The crack detection wire CDW may be located in the non-display area NDA. One end of the crack detection wire CDW may be connected to the first crack detection pad CDP1, and the other end of the crack detection wire CDW may be connected to the second crack detection pad CDP2. The crack detection wire CDW may extend along the circumference of the display panel DP. The crack detection wire CDW may be arranged not to interfere with the alignment key AK located near the corner portion CS of the display panel DP on a wiring path. For example, the crack detection wire CDW may be bent obliquely not to be in contact with the alignment key AK in the vicinity of the corner portion CS of the display panel DP. The crack detection wire CDW may be configured in a form in which a multiwire and a single wire are combined in the vicinity of the corner portion CS of the display panel DP. A detailed description thereof will be mentioned below with reference to FIG. 3.

Configurations such as a gate driver, a data driver, a timing controller, and the like for driving the pixels PX may be implemented in the chip on film COF, the printed circuit board PCB, and/or the like. However, the embodiments are not necessarily limited thereto. For example, the above-described configurations may be implemented in the non-display area NDA of the substrate SUB.

FIG. 3 is an enlarged view of area X in FIG. 2.

Referring to FIG. 3, the crack detection wire CDW may include a first wire portion WS1, a second wire portion WS2, and a third wire portion WS3. The first wire portion WS1, the second wire portion WS2, and the third wire portion WS3 may mean portions of the crack detection wire CDW arranged near the alignment key AK or the corner portion CS of the display panel DP (see FIG. 2).

The first wire portion WS1 may include a plurality of wires. When the first wire portion WS1 is a multiwire, the crack detection performance of the display panel DP (see FIG. 2) may be relatively improved compared to when the first wire portion WS1 is a single wire. The plurality of wires of the first wire portion WS1 may refer to portions of the crack detection wire CDW. For example, the first wire portion WS1 may include a first straight portion SS1, a first bending portion BS1, a second straight portion SS2, a second bending portion BS2, and a third straight portion SS3.

The first straight portion SS1 may extend in a first diagonal direction DDR1 not to interfere with the alignment key AK. The first diagonal direction DDR1 may refer to a direction oblique to the first direction DR1.

The first bending portion BS1 may be bent at the first straight portion SS1 and extend in a third diagonal direction DDR3. The third diagonal direction DDR3 may be orthogonal to the first diagonal direction DDR1, but embodiments are not necessarily limited thereto. For example, the third diagonal direction DDR3 may mean a direction oblique to the first diagonal direction DDR1.

The second straight portion SS2 may be bent at the first bending portion BS1 and extend in a second diagonal direction DDR2 opposite to the first diagonal direction DDR1. The second straight portion SS2 may be spaced apart from the first straight portion SS1. According to some embodiments, the second straight portion SS2 may extend in a direction parallel to the first straight portion SS1, and the first bending portion BS1 may extend in a direction perpendicular to the first straight portion SS1 and the second straight portion SS2.

The second bending portion BS2 may be bent at the second straight portion SS2 and extend in the third diagonal direction DDR3.

The third straight portion SS3 may be bent at the second bending portion BS2 and extend in the first diagonal direction DDR1. The third straight portion SS3 may be spaced apart from the second straight portion SS2. According to some embodiments, the third straight portion SS3 may extend in a direction parallel to the second straight portion SS2.

As illustrated in FIG. 3, the first straight portion SS1, the second straight portion SS2, and the third straight portion SS3 may have linear shapes so as to be formed in a straight line. Embodiments according to the present disclosure are not necessarily limited thereto. For example, according to some embodiments, the first straight portion SS1, the second straight portion SS2, and the third straight portion SS3 may have a curved shape such that the curvatures follow the shape of each other.

The second wire portion WS2 may include a single wire. The single wire of the second wire portion WS2 may refer to a portion of the crack detection wire CDW. For example, the second wire portion WS2 may include a third bending portion BS3.

The third bending portion BS3 may be bent at the third straight portion SS3 not to interfere with the alignment key AK and extend in a fourth diagonal direction DDR4 opposite to the third diagonal direction DDR3.

The third wire portion WS3 may include a plurality of wires. When the third wire portion WS3 is a multiwire, the crack detection performance of the display panel DP (see FIG. 2) may be relatively improved compared to when the third wire portion WS3 is a single wire. The plurality of wires of the third wire portion WS3 may refer to portions of the crack detection wire CDW. For example, the third wire portion WS3 may include a fourth straight portion SS4, a fourth bending portion BS4, a fifth straight portion SS5, a fifth bending portion BS5, and a sixth straight portion SS6.

The fourth straight portion SS4 may be bent at the third bending portion BS3 (or the second wire portion WS2) to extend in the first diagonal direction DDR1.

The fourth bending portion BS4 may be bent at the fourth straight portion SS4 and extend in the third diagonal direction DDR3.

The fifth straight portion SS5 may be bent at the fourth bending portion BS4 and extend in the second diagonal direction DDR2. The fifth straight portion SS5 may be spaced apart from the fourth straight portion SS4.

The fifth bending portion BS5 may be bent at the fifth straight portion SS5 and extend in the third diagonal direction DDR3.

The sixth straight portion SS6 may be bent at the fifth bending portion BS5 and extend in the first diagonal direction DDR1. The sixth straight portion SS6 may be spaced apart from the fifth straight portion SS5.

As illustrated in FIG. 3, the fourth straight portion SS4 and the fifth straight portion SS5, and the sixth straight portion SS6 may have linear shapes so as to be formed in a straight line. Embodiments according to the present disclosure are not necessarily limited thereto. For example, according to some embodiments the fourth straight portion SS4 and the fifth straight portion SS5, and the sixth straight portion SS6 may have a curved shape such that the curvatures follow the shape of each other.

A width w of the crack detection wire CDW may be constant throughout the crack detection wire CDW. For example, a width w of the first straight portion SS1, a width w of the first bending portion BS1, a width w of the second straight portion SS2, a width w of the second bending portion BS2, a width w of the third straight portion SS3, a width w of the third bending portion BS3, a width w of the fourth straight portion SS4, a width w of the fourth bending portion BS4, a width w of the fifth straight portion SS5, a width w of the fifth bending portion BS5, and a width w of the sixth straight portion SS6 may be the same as each other. For example, the width w may be 3 micrometers (μm), but embodiments are not necessarily limited thereto.

A distance d between the first straight portion SS1 and the second straight portion SS2 and a distance d between the second straight portion SS2 and the third straight portion SS3 may be the same. In addition, a distance d between the fourth straight portion SS4 and the fifth straight portion SS5 and a distance d between the fifth straight portion SS5 and the sixth straight portion SS6 may be the same. For example, the distance d may be approximately 3 μm, but embodiments are not necessarily limited thereto.

When the second wire portion WS2 is a single wire, the first wire portion WS1 may be damaged. For example, in the second wire portion WS2 which is a single wire, the current flow is smaller than that in the first wire portion WS1 which is a multiwire, so that the resistance of the second wire portion WS2 may be relatively great. The static electricity (or electric charge) introduced through the first crack detection pad CDP1 (see FIG. 2) might not be dispersed or absorbed through the second wire portion WS2, and may be accumulated in the first wire portion WS1. The static electricity (or electric charge) accumulated in the first wire portion WS1 is instantaneously discharged, so that the first wire portion WS1 may be damaged.

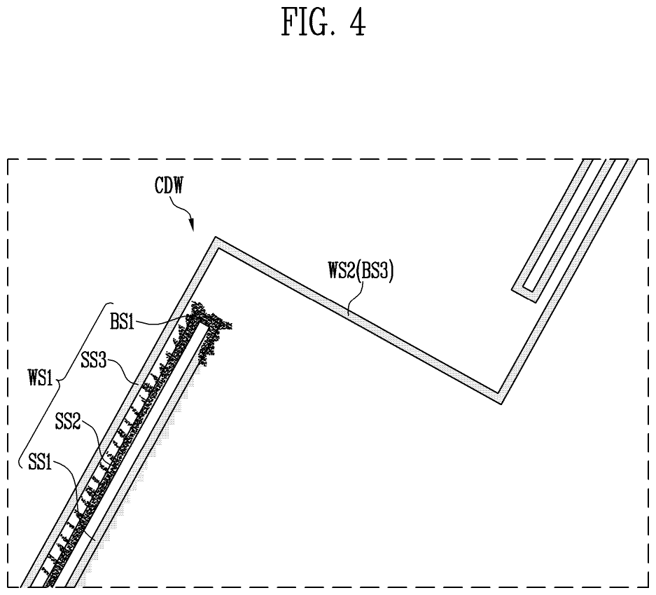

FIG. 4 is a diagram illustrating a measured electric field of the crack detection wire in FIG. 3.

Referring to FIG. 4, it may be seen that the electric field in the crack detection wire CDW is greater in the first wire portion WS1 than in the second wire portion WS2. For convenience, in FIG. 4, a part with a great electric field is shown black, and a part with a small electric field is shown light. Experimentally, the electric field of the first wire portion WS1 was measured to be great, which was approximately 1.02E8 V/m. This may be a result of the static electricity (or electric charge) introduced through the first crack detection pad CDP1 being accumulated in the first wire portion WS1 without being dispersed or absorbed through the second wire portion WS2.

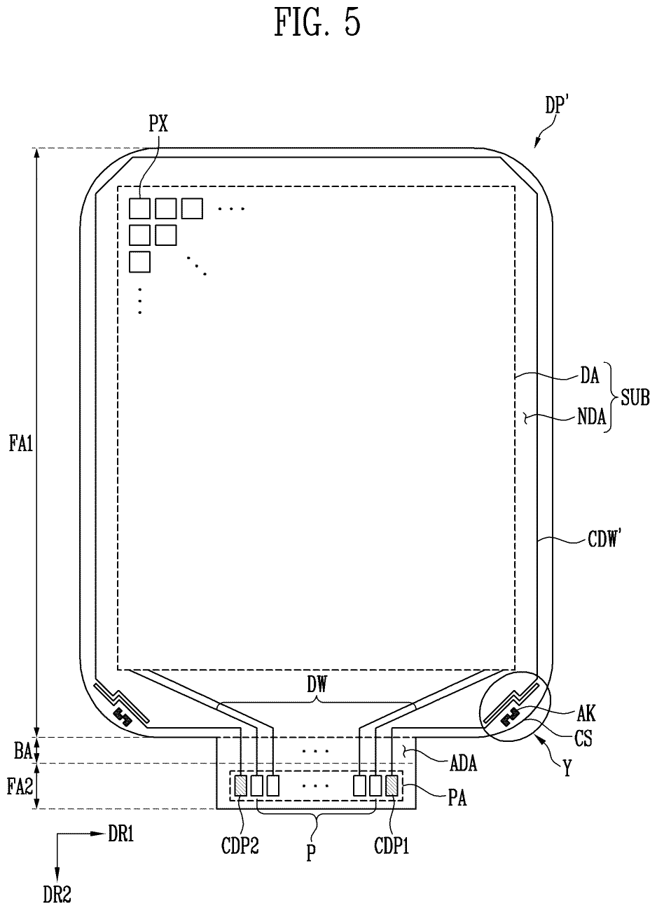

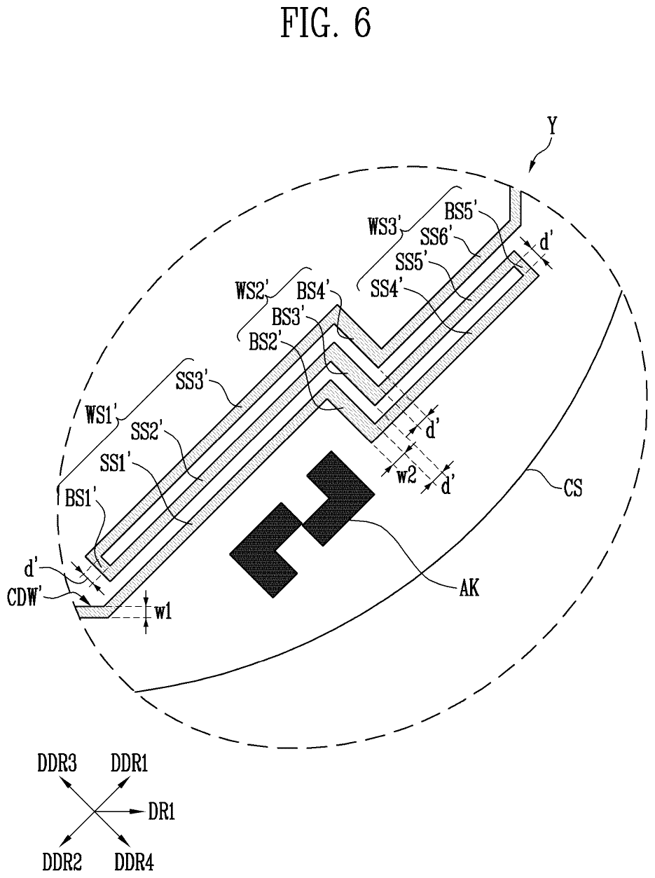

FIG. 5 schematically illustrates a display panel according to some embodiments of the present disclosure. FIG. 6 is an enlarged view of area Y in FIG. 5. Any repetitive detailed descriptions already mentioned with reference to FIG. 2 shall be simplified in or omitted from descriptions with reference to FIG. 5. Any repetitive detailed descriptions already mentioned with reference to FIG. 3 shall be simplified in or omitted from descriptions with reference to FIG. 6.

Referring to FIG. 5, the display panel DP′ may include a crack detection wire CDW′ located in the non-display area NDA. The crack detection wire CDW′ may be arranged not to interfere with the alignment key AK located near the corner portion CS of the display panel DP′ on a wiring path, and may be configured in the form of a multiwire near the corner portion CS.

Referring to FIG. 6, the crack detection wire CDW′ may include a first wire portion WS1′, a second wire portion WS2′, and a third wire portion WS3′. The first wire portion WS1′, the second wire portion WS2′, and the third wire portion WS3′ may mean portions of the crack detection wire CDW′ arranged near the alignment key AK or the corner portion CS of the display panel DP′ (see FIG. 5).

The first wire portion WS1′ may be configured in the form of a multiwire including a plurality of wires. The plurality of wires of the first wire portion WS1′ may mean portions of the crack detection wire CDW′. For example, the first wire portion WS1′ may include a first straight portion SS1′, a second straight portion SS2′, a first bending portion BS1′, and a third straight portion SS3′.

The first straight portion SS1′ may extend in the first diagonal direction DDR1 not to interfere with the alignment key AK.

The second straight portion SS2′ may be bent at a third bending portion BS3′ of the second wire portion WS2′ and extend in the second diagonal direction DDR2. The second straight portion SS2′ may be spaced apart from the first straight portion SS1′.

The first bending portion BS1′ may be bent at the second straight portion SS2′ and extend in the third diagonal direction DDR3.

The third straight portion SS3′ may be bent at the first bending portion BS1′ and extend in the first diagonal direction DDR1. The third straight portion SS3′ may be spaced apart from the second straight portion SS2′.

The first wire portion WS1′ may be configured in the form of a multiwire having a first width w1. For example, the first straight portion SS1′, the second straight portion SS2′, the first bending portion BS1′, and the third straight portion SS3′ may have the same first width w1. For example, the first width w1 may be 3 μm, but embodiments are not necessarily limited thereto.

The second wire portion WS2′ may be configured in the form of a multiwire including a plurality of wires. The plurality of wires of the second wire portion WS2′ may mean portions of the crack detection wire CDW′. For example, the second wire portion WS2′ may include a second bending portion BS2′, the third bending portion BS3′, and a fourth bending portion BS4′.

The second bending portion BS2′ may be bent at the first straight portion SS1′ of the first wire portion WS1′ and extend in the fourth diagonal direction DDR4.

The third bending portion BS3′ may be bent at the second straight portion SS2′ of the first wire portion WS1′ and extend in the fourth diagonal direction DDR4. The third bending portion BS3′ may be spaced apart from the second bending portion BS2′.

The fourth bending portion BS4′ may be bent at the third straight portion SS3′ of the first wire portion WS1′ and extend in the fourth diagonal direction DDR4. The fourth bending portion BS4′ may be spaced apart from the third bending portion BS3′.

The second wire portion WS2′ may be configured in the form of a multiwire having a second width w2 which is greater than the first width w1. For example, the second bending portion BS2′, the third bending portion BS3′, and the fourth bending portion BS4′ may have the same second width w2. For example, the second width w2 may be approximately 4 μm, but embodiments are not necessarily limited thereto.

When the second wire portion WS2′ is a multiwire, damage to the first wire portion WS1′ may be prevented, reduced, or mitigated. For example, a current flows smoothly in the first wire portion WS1′ and the second wire portion WS2′, each of which is a multiwire, so that a difference in resistance between the first wire portion WS1′ and the second wire portion WS2′ may be insignificant or there is no difference in resistance. The static electricity (or electric charge) introduced through the first crack detection pad CDP1 (see FIG. 5) may be dispersed or absorbed through the second wire portion WS2′ and might not be accumulated in the first wire portion WS1′. That is, the static electricity is evenly distributed between the first wire portion WS1′ and the second wire portion WS2′, so that instantaneous electrostatic discharge might not occur in the first wire portion WS1′. Therefore, the function of the first wire portion WS1′ is normally maintained, so that the crack detection capability of the display panel DP′ (see FIG. 5) may be relatively improved.

In addition, when the width of the second wire portion WS2′ is greater than the width of the first wire portion WS1′ (w2>w1), the resistance of the second wire portion WS2′ relatively decreases, so that the static electricity (or electric charge) introduced through the first crack detection pad CDP1 (see FIG. 5) may be more effectively dispersed or absorbed through the second wire portion WS2′. Therefore, damage to the first wire portion WS1′ due to instantaneous electrostatic discharge may be more effectively prevented, reduced, or mitigated.

The third wire portion WS3′ may be configured in the form of a multiwire including a plurality of wires. The plurality of wires of the third wire portion WS3′ may mean portions of the crack detection wire CDW′. For example, the third wire portion WS3′ may include a fourth straight portion SS4′, a fifth bending portion BS5′, a fifth straight portion SS5′, and a sixth straight portion SS6′.

The fourth straight portion SS4′ may be bent at the second bending portion BS2′ of the second wire portion WS2′ and extend in the first diagonal direction DDR1.

The fifth bending portion BS5′ may be bent at the fourth straight portion SS4′ and extend in the third diagonal direction DDR3.

The fifth straight portion SS5′ may be bent at the fifth bending portion BS5′ and extend in the second diagonal direction DDR2. The fifth straight portion SS5′ may be spaced apart from the fourth straight portion SS4′.

The sixth straight portion SS6′ may be bent at the fourth bending portion BS4′ of the second wire portion WS2′ and extend in the first diagonal direction DDR1. The sixth straight portion SS6′ may be spaced apart from the fifth straight portion SS5′.

The third wire portion WS3′ may be configured in the form of a multiwire having the first width w1. For example, the fourth straight portion SS4′, the fifth bending portion BS5′, the fifth straight portion SS5′, and the sixth straight portion SS6′ may have the same first width w1.

In summary, the crack detection wire CDW′ may have the first width w1 in the first wire portion WS1′ and the third wire portion WS3′, and the second width w2, which is greater than the first width w1, in the second wire portion WS2′.

A distance d′ between the first straight portion SS1′ and the second straight portion SS2′ and a distance d′ between the second straight portion SS2′ and the third straight portion SS3′ may be the same. In addition, a distance d′ between the second bending portion BS2′ and the third bending portion BS3′ and a distance d′ between the third bending portion BS3′ and the fourth bending portion BS4′ may be the same. Furthermore, a distance d′ between the fourth straight portion SS4′ and the fifth straight portion SS5′ and a distance d′ between the fifth straight portion SS5′ and the sixth straight portion SS6′ may be the same. For example, the distance d′ may be approximately 4 μm, but embodiments are not necessarily limited thereto. When the distance d′ between the plurality of wires constituting the crack detection wire CDW′ increases, damage to the crack detection wire CDW′ due to electrostatic discharge may be more effectively prevented, reduced, or mitigated.

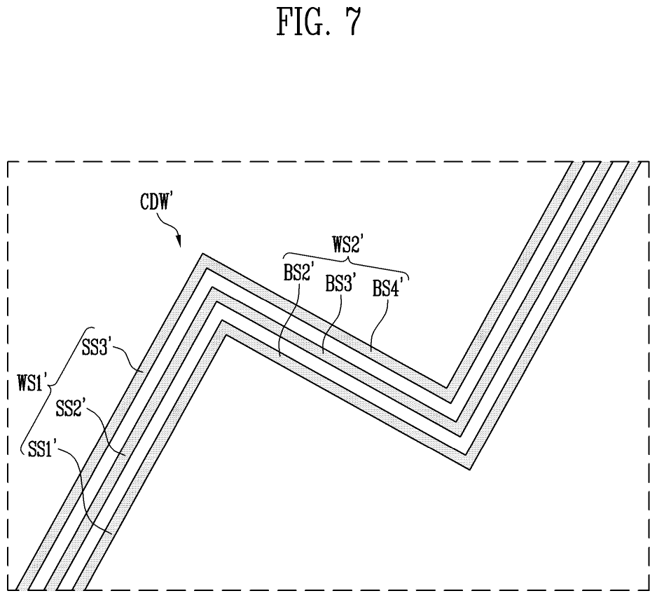

FIG. 7 is a diagram illustrating a measured electric field of the crack detection wire in FIG. 6.

Referring to FIG. 7, it may be seen that the electric field in the crack detection wire CDW′ appears uniformly in the first wire portion WS1′ and the second wire portion WS2′. Experimentally, the electric field of the first wire portion WS1′ was measured as small, which was approximately 5.27E7 V/m. Compared with the experimental results shown in FIG. 4, the electric field of the first wire portion WS1′ decreased by approximately 48.5%. This may be a result of the static electricity (or electric charge) introduced through the first crack detection pad CDP1 being dispersed or absorbed through the second wire portion WS2′, which is a multiwire, and not being accumulated in the first wire portion WS1′.

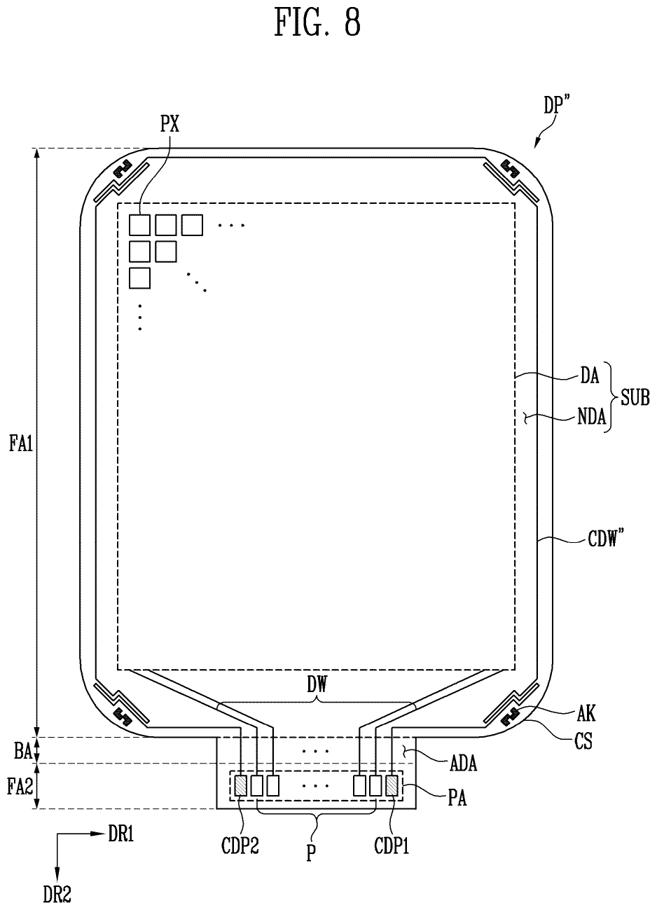

FIG. 8 schematically illustrates a display panel according to some embodiments of the present disclosure. Any repetitive detailed descriptions already mentioned with reference to FIG. 5 shall be simplified in or omitted from descriptions with reference to FIG. 8.

Referring to FIG. 8, the display panel DP″ may include the alignment key AK located at each corner portion CS. For example, the alignment key AK may be located not only at each of the lower left corner portion CS and the lower right corner portion CS of the substrate SUB (or the display panel DP″), but also in each of the upper left corner portion CS and the upper right corner portion CS.

The display panel DP″ may include a crack detection wire CDW″. The crack detection wire CDW″ may be arranged not to interfere with the alignment key AK located near the corner portion CS of the display panel DP″ on a wiring path, and may be configured in the form of a multiwire near the corner portion CS. For example, the crack detection wire CDW″ may be configured in the form of a multiwire not only in the vicinity of each of the lower left corner portion CS and the lower right corner portion CS, but also in the vicinity of each of the upper left corner portion CS and the upper right corner portion CS.

As shown in FIG. 5 and FIG. 8, the shapes of the crack detection wires CDW′ and CDW″ may be variously changed according to the position, number, shape, and the like of the alignment key AK. That is, the shapes of the crack detection wires CDW′ and CDW″ are not necessarily limited to the embodiments shown in FIG. 5 and FIG. 8. As long as each of the crack detection wires CDW′ and CDW″ is configured in the form of a multiwire near the alignment key AK, the crack detection wires CDW′ and CDW″ may fall within the scope of the present disclosure.

The display device DD (see FIG. 1) may be applied to various electronic devices. For example, the electronic devices include the display device DD described above, and may further include a module or device having an additional function other than the display device DD.

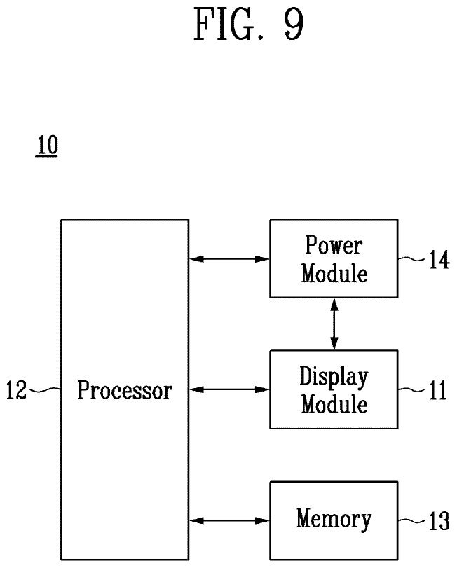

FIG. 9 schematically illustrates an electronic device according to some embodiments of the present disclosure.

Referring to FIG. 9, the electronic device 10 may include a display module 11, a processor 12, memory 13, and a power module 14.

The processor 12 may include at least one of a central processing unit, an application processor, a graphics processing unit, a communication processor, an image signal processor, or a controller.

The memory 13 may store data information necessary for an operation of the processor 12 or the display module 11. When the processor 12 executes an application stored in the memory 13, an image data signal and/or an input control signal are transmitted to the display module 11, and the display module 11 may process the received signal and output image information through a display screen.

The power module 14 may include a power supply module such as a power adapter or a battery device, and a power conversion module which converts power supplied by the power supply module to generate power necessary for an operation of the electronic device 10.

At least one of the respective components of the electronic device 10 may be included in the display device DD. In addition, one or more of individual modules which are functionally included in one module may be included in the display device DD, and individual modules other than the one or more of the individual modules may be provided separately from the display device DD. For example, the display device DD includes the display module 11, and the processor 12, the memory 13, and the power module 14 may be provided in the form of other devices in the electronic device 10 other than the display device DD.

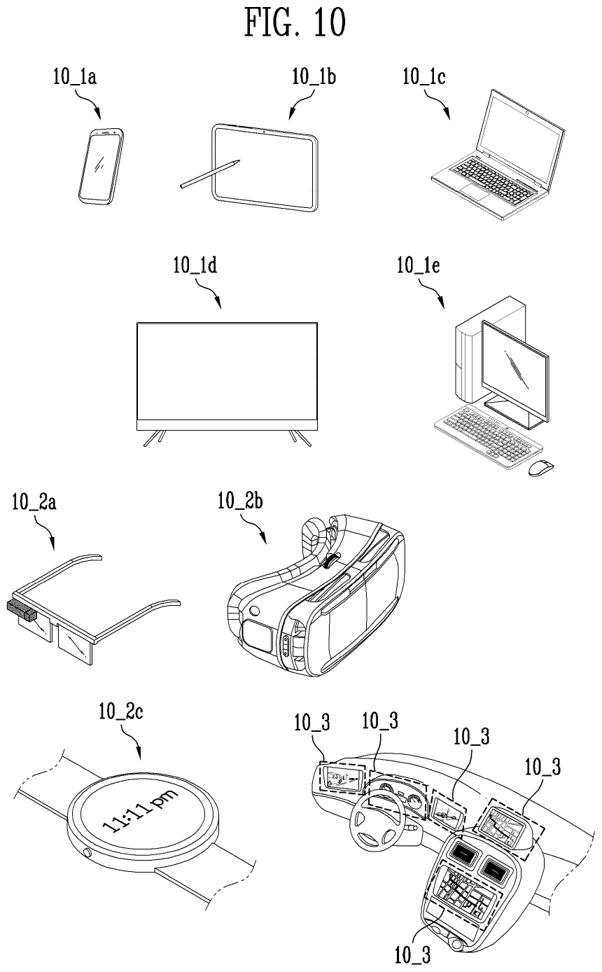

FIG. 10 schematically illustrates electronic devices according to some embodiments of the present disclosure.

Referring to FIG. 10, examples of the electronic device 10 (see FIG. 9) may include an electronic device for displaying images, such as a smartphone 10_1a, a tablet PC 10_1b, a laptop 10_1c, a television 10_1d, or a desk monitor 10_1e, as well as a wearable electronic device including a display module such as smart glasses 10_2a, a head-mounted display 10_2b, or a smart watch 10_2c, and an automotive electronic device 10_3 including a display module such as an automotive dashboard, a center fascia, a Center Information Display (CID) placed on a dashboard, or a room mirror display.

It should be noted that, although the present disclosure is described in detail in accordance with the foregoing embodiments, the foregoing embodiments are intended to describe the present disclosure and not to limit the scope of the present disclosure. Those skilled in the art to which the present disclosure pertains may understand that various modifications are possible within the scope of the technical spirit of the present disclosure.

The scope of the present disclosure should not be limited to the descriptions mentioned in the detailed description of the specification, but should be determined by the appended claims. In addition, all modifications or variations derived from the meaning and scope of the claims, and equivalents thereof, are to be construed as included within the scope of the present disclosure.

According to some embodiments of the present disclosure, damage to a crack detection wire due to the static electricity accumulation may be prevented, reduced, or mitigated. Accordingly, the accuracy of detecting whether a crack occurs in a display panel may be relatively improved.

However, the characteristics of embodiments according to the present disclosure are not limited to the characteristics described above, and may be variously extended without departing from the spirit and scope of embodiments according to the present disclosure.

What is claimed is:

1. A display panel, comprising:
a substrate including a display area and a non-display area;
a first crack detection pad and a second crack detection pad in a pad area overlapping the non-display area;
an alignment key at a corner portion of the substrate; and
a crack detection wire having one end connected to the first crack detection pad and another end connected to the second crack detection pad,
wherein the crack detection wire comprises:
a first wire portion;
a second wire portion including a plurality of wires bent from the first wire portion by the alignment key; and
a third wire portion connected to the second wire portion.

2. The display panel according to claim 1, wherein the first wire portion comprises:
a first straight portion extending in a first diagonal direction by the alignment key;
a second straight portion extending in a second diagonal direction opposite to the first diagonal direction and spaced apart from the first straight portion;
a first bending portion bent at the second straight portion and extending in a third diagonal direction; and
a third straight portion bent at the first bending portion, extending in the first diagonal direction, and spaced apart from the second straight portion.

3. The display panel according to claim 2, wherein the second wire portion comprises:
a second bending portion bent at the first straight portion and extending in a fourth diagonal direction opposite to the third diagonal direction;
a third bending portion bent at the second straight portion and extending in the fourth diagonal direction; and
a fourth bending portion bent at the third straight portion and extending in the fourth diagonal direction.

4. The display panel according to claim 3, wherein the third wire portion comprises:
a fourth straight portion bent at the second bending portion and extending in the first diagonal direction;
a fifth bending portion bent at the fourth straight portion and extending in the third diagonal direction;
a fifth straight portion bent at the fifth bending portion, extending in the second diagonal direction, and spaced apart from the fourth straight portion; and
a sixth straight portion extending in the first diagonal direction and spaced apart from the fifth straight portion.

5. The display panel according to claim 4, wherein the third bending portion is connected to the fifth straight portion.

6. The display panel according to claim 4, wherein the fourth bending portion is connected to the sixth straight portion.

7. The display panel according to claim 4, wherein a distance between the first straight portion and the second straight portion, a distance between the second straight portion and the third straight portion, a distance between the second bending portion and the third bending portion, a distance between the third bending portion and the fourth bending portion, a distance between the fourth straight portion and the fifth straight portion, and a distance between the fifth straight portion and the sixth straight portion are equal.

8. The display panel according to claim 7, wherein the distance is 4 micrometers (μm).

9. The display panel according to claim 4, wherein a second width of each of the second bending portion, the third bending portion, and the fourth bending portion is greater than a first width of each of the first straight portion, the second straight portion, the third straight portion, the first bending portion, the fourth straight portion, the fifth straight portion, the sixth straight portion, and the fifth bending portion.

10. The display panel according to claim 9, wherein the second width is 4 micrometers (μm) and the first width is 3 μm.

11. An electronic device, comprising:
a display panel; and
a processor configured to drive the display panel,
wherein the display panel comprises:
a substrate including a display area and a non-display area;
a first crack detection pad and a second crack detection pad in a pad area overlapping the non-display area;
an alignment key at a corner portion of the substrate; and
a crack detection wire having one end connected to the first crack detection pad and another end connected to the second crack detection pad, and
wherein the crack detection wire comprises:
a first wire portion;
a second wire portion including a plurality of wires bent from the first wire portion by the alignment key; and
a third wire portion connected to the second wire portion.

12. The electronic device according to claim 11, wherein the first wire portion comprises:
a first straight portion extending in a first diagonal direction by the alignment key;
a second straight portion extending in a second diagonal direction opposite to the first diagonal direction and spaced apart from the first straight portion;
a first bending portion bent at the second straight portion and extending in a third diagonal direction; and
a third straight portion bent at the first bending portion, extending in the first diagonal direction, and spaced apart from the second straight portion.

13. The electronic device according to claim 12, wherein the second wire portion comprises:
a second bending portion bent at the first straight portion and extending in a fourth diagonal direction opposite to the third diagonal direction;
a third bending portion bent at the second straight portion and extending in the fourth diagonal direction; and
a fourth bending portion bent at the third straight portion and extending in the fourth diagonal direction.

14. The electronic device according to claim 13, wherein the third wire portion comprises:
a fourth straight portion bent at the second bending portion and extending in the first diagonal direction;
a fifth bending portion bent at the fourth straight portion and extending in the third diagonal direction;
a fifth straight portion bent at the fifth bending portion, extending in the second diagonal direction, and spaced apart from the fourth straight portion; and
a sixth straight portion extending in the first diagonal direction and spaced apart from the fifth straight portion.

15. The electronic device according to claim 14, wherein the third bending portion is connected to the fifth straight portion.

16. The electronic device according to claim 14, wherein the fourth bending portion is connected to the sixth straight portion.

17. The electronic device according to claim 14, wherein a distance between the first straight portion and the second straight portion, a distance between the second straight portion and the third straight portion, a distance between the second bending portion and the third bending portion, a distance between the third bending portion and the fourth bending portion, a distance between the fourth straight portion and the fifth straight portion, and a distance between the fifth straight portion and the sixth straight portion are equal.

18. The electronic device according to claim 17, wherein the distance is 4 micrometers (μm).

19. The electronic device according to claim 14, wherein a second width of each of the second bending portion, the third bending portion, and the fourth bending portion is greater than a first width of each of the first straight portion, the second straight portion, the third straight portion, the first bending portion, the fourth straight portion, the fifth straight portion, the sixth straight portion, and the fifth bending portion.

20. The electronic device according to claim 19, wherein the second width is 4 micrometers (μm) and the first width is 3 μm.
